(19) United States
(12) Patent Application Publication
(10) Pub. No.: US 2004/0144491 A1
(43) Pub. Date: Jul. 29, 2004

(54) Plasma processing apparatus and plasma processing method

(76) Inventors: Junko Ohuchi, Yokohama-shi (JP); Tokuhisa Ohiwa, Kawasaki-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/715,523

(22) Filed: Nov. 19, 2003

(30) Foreign Application Priority Data
Nov. 20, 2002 (JP) 2002-336960

(51) Int. Cl. H01L 21/306

(52) U.S. Cl. 156/345.47

(57) ABSTRACT

A plasma processing apparatus includes a chamber in which a plate to be processed is contained, an introductory port via which a hydrogen-atom-containing gas is guided into the chamber, a lower electrode on which the plate is laid in the chamber, an upper electrode disposed opposite to the lower electrode and causing electric discharge in the chamber to produce a plasma, a power supply which supplies voltage between the lower and upper electrodes, and a metal oxide structural body disposed in a part in the chamber, the metal oxide structural body being reduced when the hydrogen-atom-containing gas is introduced.

### CROSS-REFERENCE TO RELATED APPLICATIONS

This application is based upon and claims the benefit of priority from the prior Japanese Patent Application No. 2002-336960, filed Nov. 20, 2002, the entire contents of which are incorporated herein by reference.

### BACKGROUND OF THE INVENTION

1. Field of the Invention

The present invention relates to a plasma processing technique for performing plasma processing with respect to the surface of a plate to be processed, particularly to a plasma processing apparatus and plasma processing method for use in ashing a resist, and further to a semiconductor manufacturing apparatus using the plasma processing apparatus and method.

2. Description of the Related Art

In recent years, along with the miniaturization and speed-up of semiconductor devices, parasitic capacitance between interconnections and signal propagation delay, caused by wiring resistance, have raised problems. To reduce the parasitic capacitance between interconnections, the use of low dielectric constant films (low-k films), such as an organic silicon oxide film and organic film as interlayer films has been studied.

However, after the interlayer film is processed, the resist is removed with O₂ plasma processing which has heretofore been used. Thus, the low dielectric constant film exposed in an opening is easily oxidized by an O radical. As a result, organic components in the low dielectric constant film evaporate to form a modified layer on the surface, and there is a problem that the modified layer absorbs moisture, which raises a dielectric constant.

To reduce the modified layer, an amount of O radicals is preferably reduced as much as possible to perform resist ashing only with ions. Therefore, as a plasma processing apparatus, an RIE apparatus is more suitable rather than a down flow type for use in usual resist ashing. However, even when the RIE apparatus is used, it is impossible to completely remove the O radical, and the modified layer is formed even with a small amount of O radicals. Therefore, a method of peeling the resist with the plasma processing using a gas other than O₂ has been proposed.

In the resist ashing using a gas other than O₂, there is a method using plasma of gases containing a hydrogen or nitrogen atom, such as H₂, N₂, NH₃, or a mixture gas containing these gases. When the plasma of these gases are used in removing the resist, the modified layer formed on the low dielectric constant film can largely be reduced as compared with the modified layer by the O₂ plasma processing (e.g., see Jpn. Pat. Appln. KOKAI Publication No. 2002-9050).

However, it has been found in experiments by the present inventors that the modified layer is not completely eliminated even with the use of this method. A reason for this is supposedly that H radicals generated in the plasma using the gas containing hydrogen atoms volatize organic components in the low dielectric constant film by reduction reaction, the processed film is exposed to the atmosphere and accordingly oxidized and, as a result, the modified layer is formed in the same manner as in the O radicals. Even when the gas plasma not containing the hydrogen atoms are used to remove the resist, the hydrogen atoms are contained in the resist material, and the H radicals are surely produced in the plasma. In this manner, the H radicals also have a problem that the radicals react with the low dielectric constant film and the modified layer is formed to raise a dielectric constant, although the problem is not as serious as that of the O radicals.

Another problem lies in a fluctuation of a resist ashing rate of the plasma processing apparatus. In a process chamber in which the plasma processing is carried out, materials that are not easily volatized, such as reaction products with the resist and metal impurities brought from a wafer, are accumulated. Especially, in a resist ashing treatment of the wafer including a Cu wiring, there is a possibility that Cu residuals stick onto the wafer, and Cu is sputtered to stick to the inside of the process chamber during the ashing. When Cu sticks to the inside of the process chamber, the H radicals are consumed by Cu which has stuck, and the ashing rate of the resist is deteriorated.

When the ashing rate largely drops, due to the sticking of the accumulated material in the process chamber, the chamber needs to be cleaned. However, for this, the fluctuation of the ashing rate needs to be detected in real time. There is a method of detecting the end of the resist ashing from a surface state of the plate to be processed (e.g., see Jpn. Pat. Appln. KOKAI Publication No. 2001-189305 or U.S. Pat. No. 6,492,186), but even in this method it is difficult to detect the ashing rate itself. Therefore, it has been difficult to judge an exact cleaning timing.

Therefore, there has been a demand for realization of a plasma processing apparatus and a semiconductor manufacturing apparatus which can be applied to the ashing of the resist by the plasma processing using a hydrogen-containing gas and in which a concentration of hydrogen atoms in the process chamber can be decreased and which can inhibit the low dielectric constant film from being modified by the hydrogen atoms.

Moreover, there has been a demand for the realization of the plasma processing apparatus and plasma processing method in which the fluctuation of the ashing rate and the cleaning timing of the process chamber can be detected.

### BRIEF SUMMARY OF THE INVENTION

According to a first aspect of the present invention, provided is a plasma processing apparatus comprising:

a chamber in which a plate to be processed is contained;

an introductory port via which a hydrogen-atom-containing gas is guided into the chamber;

a lower electrode on which the plate to be processed is laid in the chamber;

an upper electrode which is disposed opposite to the lower electrode and which causes electric discharge in the chamber to produce a plasma;

a power supply which supplies voltage between the lower electrode and the upper electrode; and

a metal oxide structural body disposed in a part in the chamber, the metal oxide structural body being reduced when the hydrogen-atom-containing gas is introduced.

According to a second aspect of the present invention, there is provided a plasma processing apparatus comprising:

a chamber in which a plate to be processed is contained;

an introductory port via which a predetermined gas is guided into the chamber;

a lower electrode on which the plate to be processed is laid in the chamber;

an upper electrode which is disposed opposite to the lower electrode and which causes electric discharge in the chamber to produce a plasma;

a power supply which supplies voltage between the lower electrode and the upper electrode; and

a light emitting monitor which monitors intensity of emission by hydrogen atoms in the plasma in the chamber.

According to a third aspect of the present invention, there is provided a plasma processing method comprising:

guiding a predetermined gas into a chamber in which a plate to be processed including a resist pattern on the surface is contained;

producing a plasma by electric discharge in the chamber;

ashing the resist pattern of the plate to be processed; and

monitoring a fluctuation of emission intensity of hydrogen atoms from an initial state with a photo sensor in order to detect a fluctuation of an ashing rate of the resist or a cleaning timing of the chamber.

### BRIEF DESCRIPTION OF THE SEVERAL VIEWS OF THE DRAWING

FIG. 1 is a schematic configuration diagram showing a plasma processing apparatus according to a first embodiment of the present invention;

FIG. 2 is a top plan view of an example of a metal oxide structural body 20 in FIG. 1;

FIG. 3 is a top plan view of another example of the metal oxide structural body 20 in FIG. 1;

FIG. 4 is a top plan view of a further example of the metal oxide structural body 20 in FIG. 1;

FIG. 5 is a perspective view showing a cylindrical metal oxide structural body;

FIG. 6 is a schematic diagram of the plasma processing apparatus using the cylindrical metal oxide structural body of FIG. 5;

FIGS. 7 to 9 are sectional views of a semiconductor device, showing an ashing process of a resist in the first embodiment in a stepwise manner;

FIGS. 10 to 14 are sectional views of the semiconductor device, showing a process of forming a trench for wiring, which is subsequent to resist ashing in the first embodiment in a stepwise manner;

FIG. 15 is a schematic configuration diagram showing the plasma processing apparatus according to a second embodiment;

FIG. 16 is a diagram showing a relation between a discharge time in an NH₃ process and a resist ashing rate, and a relation between a discharge time in an NH₃ process and hydrogen atom emission intensity ratio;

FIG. 17 is a diagram showing a relation between the discharge time in an O₂ process and the resist ashing rate, and a relation between a discharge time in an NH₃ process and hydrogen atom emission intensity ratio; and

FIGS. 18 to 20 are sectional views of the semiconductor device showing the ashing process of the resist in the second embodiment in the stepwise manner.

### DETAILED DESCRIPTION OF THE INVENTION

In embodiments of the present invention described later, a metal oxide structural body causing reduction reaction with hydrogen atoms is disposed in a part of a chamber, and accordingly the hydrogen atoms produced by a plasma can be consumed by the reaction with the metal oxide structural body. Therefore, a concentration of hydrogen atoms in the plasma can be decreased, and a low dielectric constant film can be inhibited from being modified by ashing of a resist.

Moreover, since an ashing rate of a resist is proportional to the concentration of hydrogen atoms in the plasma, intensity of emission by the hydrogen atoms in the plasma in a chamber can be monitored to detect the rate during the ashing. Therefore, it is possible to detect a fluctuation of the ashing rate or a cleaning timing of a process chamber based on a monitor output.

The embodiments of the present invention will hereinafter be described with reference to the drawings.

(First Embodiment)

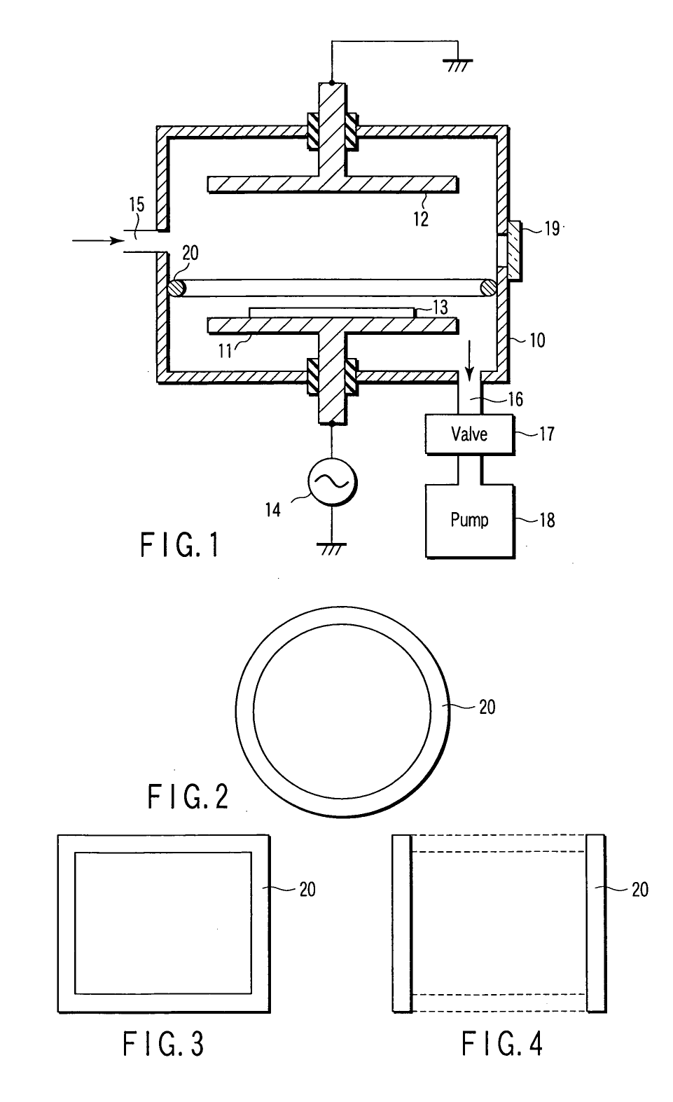

FIG. 1 is a schematic configuration diagram of a plasma processing apparatus according to a first embodiment of the present invention.

In FIG. 1, reference numeral 10 denotes a vacuum process chamber, and a lower electrode 11 is disposed opposite to an upper electrode 12 in the chamber 10. The lower electrode 11 also serves as a wafer stage, and a plate to be processed 13 such as a semiconductor wafer is laid on the lower electrode 11. The lower electrode 11 is connected to a high-frequency power supply 14 with 13.56 MHz, the upper electrode 12 is grounded, and a high-frequency power is applied between these electrodes 11, 12 to cause electric discharge.

The chamber 10 includes a gas introductory port 15 and gas exhaust port 16. Via the gas introductory port 15, a gas containing hydrogen atoms is guided while a flow rate is adjusted so as to obtain a predetermined flow rate. A vacuum pump 18 is connected to the gas exhaust port 16 via a throttle valve 17, and accordingly the inside of the chamber 10 is controlled so as to obtain a predetermined pressure.

The gas guided into the chamber 10 is excited by the electric discharge between the electrodes 11, 12, and accordingly a plasma is produced above the wafer stage 11. A window 19 is disposed in a wall surface of the chamber 10, and spectrophotometry of the plasma is performed. For an inner material of the chamber 10, an alumina, quartz, and the like are usually used so as to prevent reaction from being caused with excited gas species.

A configuration described above is basically similar to that of a conventional apparatus, and additionally in the present apparatus, an annular member 20 is applied to an inner wall surface of the chamber 10 as a metal oxide structural body causing reduction reaction with hydrogen atoms. The annular member 20 is formed of a metal piece coated with Cu, and the surface is oxidized. That is, the surface of the annular member 20 is of Cu oxide. When a horizontal cross section of the chamber 10 is circular, the annular member 20 may also be formed to be circular as shown in FIG. 2. When the horizontal cross section of the chamber 10 is rectangular, the annular member 20 may also be formed to be rectangular as shown in FIG. 3. The annular member 20 does not have to be necessarily loop-shaped, and may also be cut halfway as shown in FIG. 4.

The above-described apparatus was used to produce the plasma and to perform the spectrophotometry. First, in a state in which the annular member 20 is not disposed, that is, in the same configuration as that of a conventional apparatus, 200 sccm of an NH₃ gas was guided into the chamber 10, pressure was set to 30 Pa, a high-frequency power of 600 W was applied to produce the plasma, and the spectrophotometry was carried out. As a result, it was found that a large amount of hydrogen atoms were produced. A resist ashing rate in this condition was about 250 nm/min.

Next, in a state in which the annular member 20 was disposed on the surface of the inner wall of the process chamber 10, the spectrophotometry was carried out on the same condition as described above. As a result, the hydrogen atom concentration largely dropped. The resist ashing rate dropped by about 200 nm/min which was 20 percent. Emission intensity of the hydrogen atom in the presence of the annular member 20 was compared with that without the annular member 20. When the emission intensity without the metal oxide structural body 20 was assumed as 1, the intensity was about the half in the presence of the annular member 20. The Cu surface formed Cu oxide (Cu₂O), but it was considered that the surface was reduced by the hydrogen atoms and the following reaction took place.

Cu₂O+2H→2Cu+H₂O↑

The decrease of the hydrogen atoms causes the drop of the ashing rate, but the reaction with the resist mainly by ions of NHx, and the like is dominant. Therefore, it is considered that although the hydrogen atom concentration is reduced by half, the resist ashing rate drops by about 20 percent.

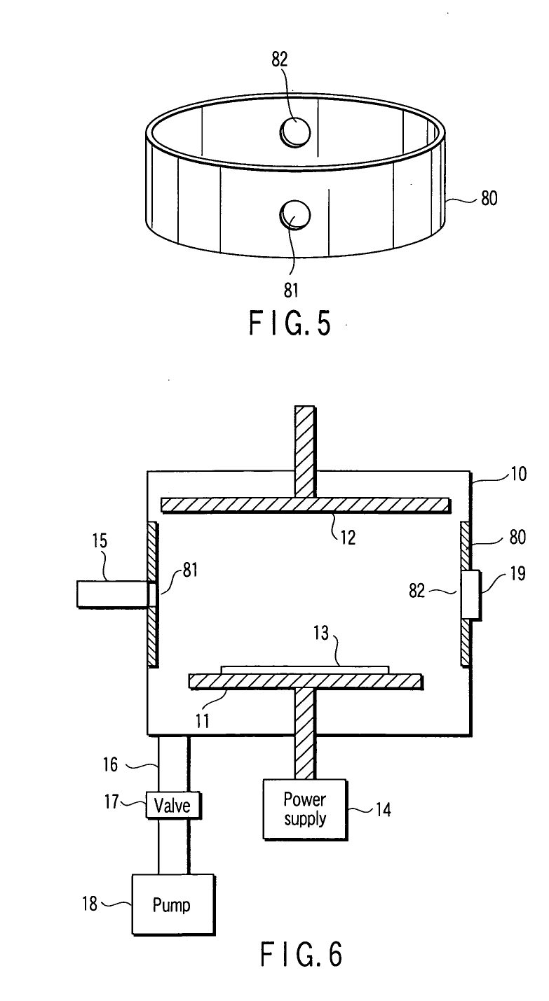

It is to be noted that the metal oxide structural body is not limited to the annular member 20 structured as shown in FIG. 1, and a cylindrical member 80 shown in FIG. 5 may also be used. As shown in FIG. 6, the cylindrical member 80 is closely fixed to the inner surface of the chamber 10 so as to surround a region between the electrodes 11, 12, a through hole 81 is disposed in a portion including the gas introductory port 15, and a through hole 82 is disposed in a portion including the window 19. Moreover, the inner surface of the cylindrical member 80 is coated with Cu. Here, the horizontal cross section of the chamber 10 was assumed to be circular, and the metal oxide structural body was formed in a cylindrical shape. However, when the horizontal cross section of the chamber 10 is rectangular, the metal oxide structural body may be formed to have a rectangular tube shape.

In this manner, when the metal oxide structural body is formed according to the inner shape of the process chamber, an inner surface unevenness of the chamber 10 due to the metal oxide structural body can substantially be reduced. Therefore, an influence given onto the plasma by the shape itself of the metal oxide structural body can be reduced. Furthermore, since the surface area of the metal oxide structural body in contact with the plasma increases, a large effect of reducing the hydrogen atoms can be fulfilled.

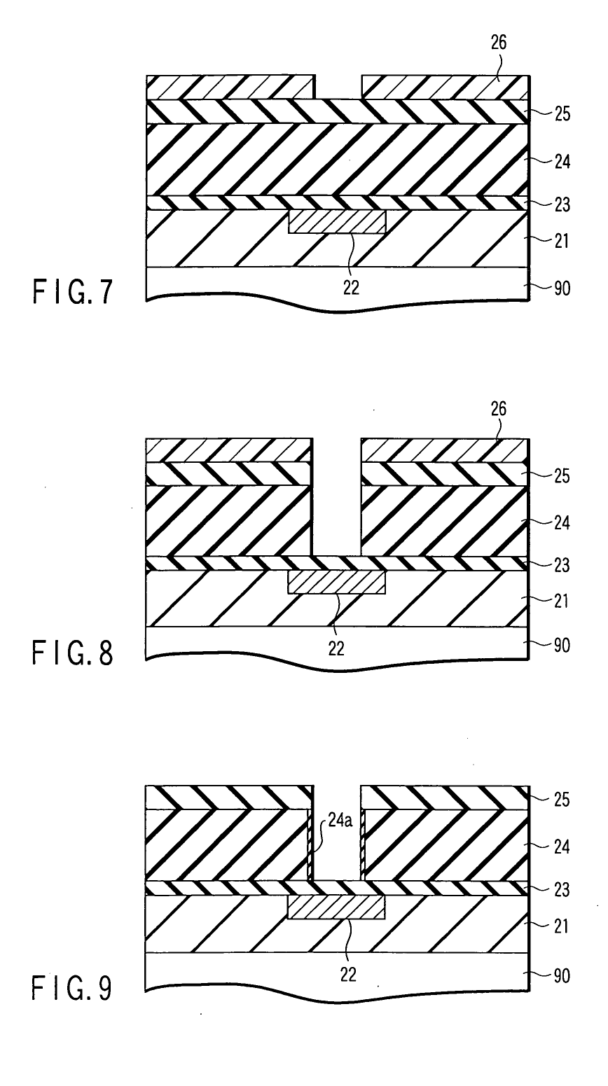

FIGS. 7 to 9 are sectional views showing steps of forming a via hole in a low dielectric constant film structure formed on a wafer.

FIG. 7 shows a state in which a resist pattern is formed in an uppermost layer of a stacked body. That is, a Cu wiring 22 is buried/formed in a surface portion of an insulating film 21 on a wafer 90, and an SiC film 23 is further formed as a Cu diffusion preventive film. Further on the film, a low dielectric constant film 24 whose specific dielectric constant is 2.8 or less, preferably about 2.5 or less, is formed. In this low dielectric constant film 24, for example, organic silicon oxide films such as polymethyl siloxane and organic films such as polyarylene-ether can be used.

A tetraethylorthosilicate (TEOS) film 25 is formed on the low dielectric constant film 24, and a resist 26 having a desired pattern is formed on the film. Here, the TEOS film 25 prevents the surface from being modified during the resist ashing. For the insulating film 25, a material having a high dielectric constant may also be used without any problem, because the insulating film can be scraped/removed during chemical mechanical polishing (CMP) after forming the pattern and depositing the Cu film via a barrier metal.

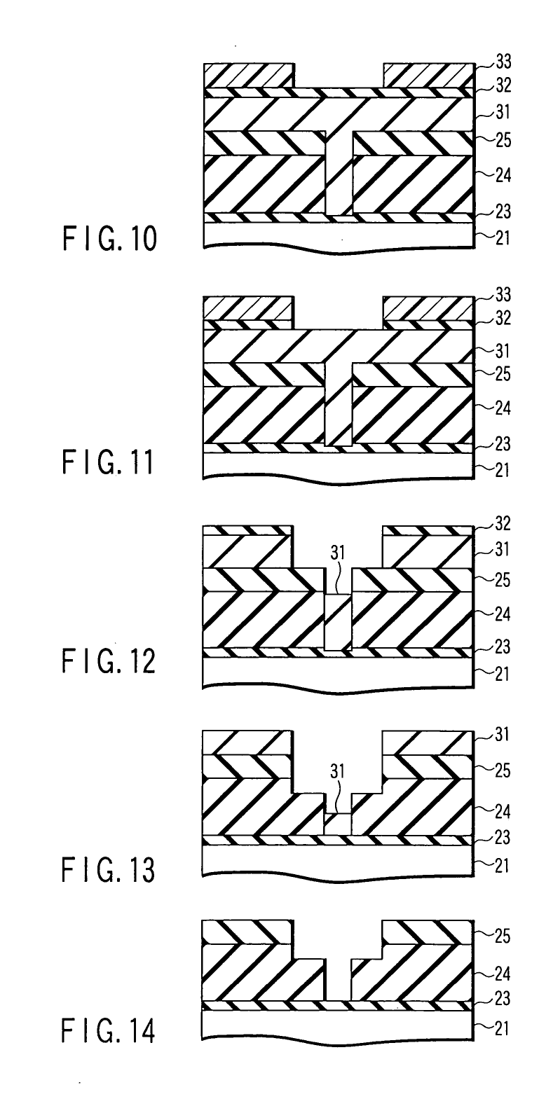

FIG. 8 shows a state in which the resist 26 is used as a mask to process the TEOS film 25 and low dielectric constant film 24 by dry etching, and the pattern of the via hole is formed. FIG. 9 shows a state in which the resist 26 is peeled by the ashing by the plasma processing. A modified layer 24a is formed on the side surface of the low dielectric constant film 24 exposed to the via hole.

The plasma processing apparatus described above is used to remove the resist as shown in FIGS. 8 and 9. To check the amount of the modified layer 24a, after the ashing, the layer from which organic components have been removed and which has been oxidized is immersed in a diluted hydrofluoric acid at a rate of 1:100 for ten seconds, and dissolved. The ashing is performed on the same condition as described above, and a time for ashing the resist having an amount of 500 nm is calculated from the ashing rate to determine an ashing time of the resist.

When the scraped amount of the low dielectric constant film 24 was checked before/after the treatment with the diluted hydrofluoric acid, the amount was 15 nm without any annular member 20. It was also found that the amount was 8 nm and small, when the annular member 20 was disposed. In the presence of the annular member 20, as compared with the absence of the annular member 20, the resist ashing rate dropped by percent, due to a decrease in the hydrogen atom concentration. Therefore, the ashing time increased by 25%, but a modified amount with respect to the low dielectric constant film 24 was substantially half. As a result, it is apparent that it is important to reduce the hydrogen atom concentration in the plasma in order to inhibit the low dielectric constant film 24 from being modified.

In this manner, according to the present embodiment, the metal oxide structural body 20 such as Cu which causes the reduction reaction with the hydrogen atom in the plasma is disposed in the chamber 10. Accordingly, the hydrogen atoms produced in the plasma are consumed by the reduction reaction with a metal oxide, and the hydrogen atom concentration in the process chamber 10 decreases. As a result, in the ashing processing of the resist, the low dielectric constant film 24 can be inhibited from being modified by the hydrogen atom.

It is to be noted that the metal oxide structural body 20 is not limited to the Cu oxide, and any material may also be used as long as the reduction reaction is caused with the hydrogen atom. When a position of the metal oxide structural body 20 is in the vicinity of the plasma, an effect can be anticipated in any portion of the position. However, a place where ion sputtering exists such as the vicinity of a lower electrode is undesirable, because the metal oxide structural body 20 is sputtered and the wafer 13 is possibly made dirty. The metal oxide structural body 20 is preferably disposed in a position in the vicinity of the plasma, and the position which is out of ion irradiation from the plasma, that is, which is not irradiated with ions from the plasma.

Moreover, instead of disposing the metal oxide structural body 20, a part of a component in the chamber 10 may directly be coated with metal materials such as Cu and Ag and the surface of the part may also be oxidized.

Furthermore, the present embodiment is not necessarily limited to the ashing of the resist, and may also be applied to the ashing of carbon as follows. FIGS. 10 to 14 are sectional views showing a method of using CMP to form a trench for the buried wiring.

After the state shown in FIG. 9, as shown in FIG. 10, a carbon film 31 is deposited on the TEOS film 25 so as to fill in the via hole, a spin on glass (SOG) film 32 is further formed, and still further the pattern of a resist 33 is formed.

Subsequently, as shown in FIG. 11, the resist 33 is used as the mask to selectively etch the SOG film 32 by RIE. Subsequently, as shown in FIG. 12, the SOG film 32 is used as the mask to selectively etch the carbon film 31. In this state, a part of the carbon film 31 remains in the via hole.

Next, as shown in FIG. 13, the SOG film 32 and carbon film 31 are used as the mask to selectively etch the TEOS film 25, and further the surface portion of the low dielectric constant film 24 is selectively etched. At this time, the SOG film 32 is eliminated during the etching of the TEOS film 25, and only the carbon film 31 remains on the surface after the etching of the low dielectric constant film 24.

Subsequently, as shown in FIG. 14, the carbon film 31 is removed by the ashing. During the removing of the carbon film 31, the low dielectric constant film 24 is exposed. When the plasma processing apparatus of the present embodiment is used, the modified layer is inhibited from being formed.

(Second Embodiment)

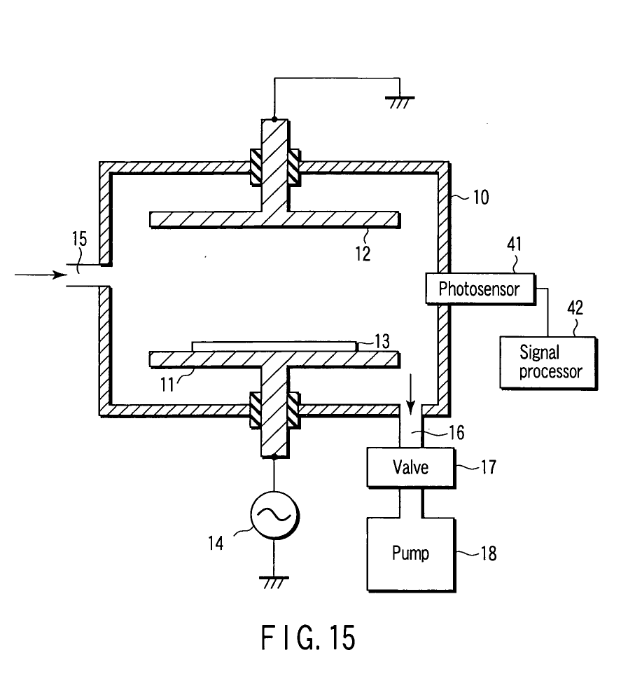

FIG. 15 is a schematic configuration diagram showing the plasma processing apparatus according to a second embodiment of the present invention. It is to be noted that the same components as those of FIG. 1 are denoted with the same reference numerals, and detailed description is omitted.

A basic structure is similar to that of FIG. 1, but a Cu piece which is the annular member 20 is not disposed. Moreover, a photo sensor 41 for monitoring emission of the plasma is disposed on a part of the wall surface of the chamber 10, and a detection output is supplied to a signal processor 42. Here, the photo sensor 41 detects a wavelength of 656 nm in which a largest change is seen in emission wavelengths of the hydrogen atom.

In this configuration, the emission intensity detected by the photo sensor 41 is taken in as a signal, and the signal is processed by the signal processor 42. Accordingly, the emission intensity of the plasma can be monitored. The emission of hydrogen has wavelengths of 656 nm, 486 nm, and the like. When the emission intensity of the wavelength is monitored by the photo sensor 41, the increase/decrease of the hydrogen atom concentration is seen. In a clean state inside the process chamber 10, the plasma is produced, and the emission intensity of the hydrogen atoms in this case is stored beforehand. Thereafter, the wafer is treated, and the emission intensity of the hydrogen atoms is appropriately monitored. Accordingly, the fluctuation of the ashing rate or the cleaning timing of the process chamber 10 can be known.

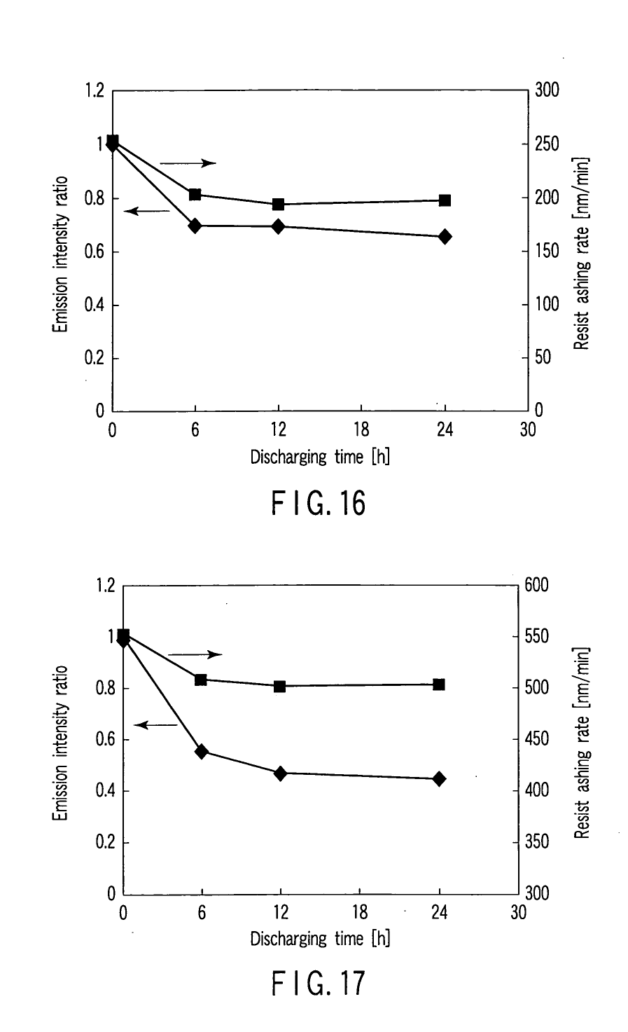

FIG. 16 shows a graph indicating a relation between a discharging time in an NH₃ process and the resist ashing rate, and a relation between a discharging time in an NH₃ process and the concentration of the hydrogen atoms (emission intensity ratio) in a state in which the plasma processing apparatus is used to carry out a process for removing the resist of the wafer on which the Cu wiring is formed. In the ashing conditions, an NH₃ flow rate is 200 sccm, pressure is 30 Pa, RF power is 600 W, and temperature is 25° C.

Usually, in management of the ashing rate of the resist, the wafer coated with resist is periodically ashed to measure a film thickness, or an end point monitor using the photo sensor is used to calculate the rate, and QC management is carried out in which comparison is carried out every time. However, in the present embodiment, when the hydrogen atom concentration is only monitored, the fluctuation of the ashing rate can be checked, and the wafer for QC is not consumed. In the conventional QC, a long-term fluctuation can be monitored, but it is difficult to capture a short-period fluctuation for each lot, but it is possible to monitor the fluctuation every time the fluctuation needs to be checked in the present embodiment.

First, the resist ashing rate and the emission intensity of the hydrogen atoms were measured in a clean state in which there was no contamination of Cu in the process chamber 10 (when the Cu wafer was not treated or immediately after the wafer was cleaned). Thereafter, the resist removing process was performed on the wafer in which Cu was exposed in an outer peripheral portion as described later, and the resist ashing rate and emission intensity were measured at an accumulated discharging time of 6 h, 12 h, 24 h. The resist ashing rate was about 250 nm/min before wafer treatment, but dropped to about 200 nm/min after a discharging time of 6 h. Even when the discharging time was lengthened more, the rate did not drop. Assuming that a value of the emission intensity before the process was 1, the intensity rapidly dropped to about 0.6 in the discharging time of 6 h, and did not change much after that.

In this manner, it was found that the resist ashing rate had a correlation with the change of the emission intensity of the hydrogen atom. After the discharging for 24 hours, the process chamber 10 was opened to the atmosphere and checked. Then, Cu sticking to the components in the process chamber 10 was seen. It was confirmed that Cu stuck to the inside of the process chamber 10, the hydrogen atoms were consumed by Cu, and the rate dropped by continuous treatment of the wafer on which Cu was disposed on the outer peripheral portion.

Here, the emission intensity was measured in a state in which an Si wafer was disposed as the plate to be processed in the process chamber 10. However, even with the use of an Si wafer on which the resist is formed, the change of the emission intensity is similarly seen. If possible, the discharging may also be carried out without disposing the wafer in the process chamber 10.

In this experiment, only the wafer in which Cu is exposed in the peripheral portion is continuously processed under the same condition, but in actual manufacturing, the wafer having a different exposed amount of Cu is treated under various conditions. Therefore, the discharging time required until the ashing rate drops differs depending on cases. Moreover, when the ashing rate rapidly drops, due to the sticking of Cu, this cannot immediately be handled by a periodic inspection about once in a week, and a problem occurs that the resist remains. In the present embodiment, when the hydrogen atom concentration is monitored, the fluctuation of the ashing rate can quickly be detected, and the wafer for QC is not required.

FIG. 17 is a graph showing a relation between the discharging time in an O₂ process and the resist ashing rate, and a relation between the discharging time in an O₂ process and the concentration of the hydrogen atoms (emission intensity ratio), in a state in which the plasma processing apparatus is used to carry out the process for removing the resist of the wafer on which the Cu wiring is formed. The ashing conditions include an O₂ flow rate of 150 sccm, pressure of 30 Pa, RF power of 500 W, and temperature at 25° C.

Even in the ashing using the gas which does not contain any hydrogen atoms, such as O₂, it is possible to monitor the rate in the same manner as in NH₃, as shown in FIG. 17. When an O₂ plasma is produced with a Si wafer disposed, or without disposing anything in the process chamber 10, only the emission of oxygen atoms is observed, and the emission of hydrogen atoms is not observed. However, when the wafer coated with the resist is disposed as the plate to be processed by the resist removing process in the process chamber 10 to produce the O₂ plasma, the emission of hydrogen atoms is observed. This is because the resist is ashed by O radicals, and the hydrogen atoms contained in the resist film are discharged into the plasma.

The emission intensity of the hydrogen atoms is monitored in this manner in the state in which the wafer coated with the resist is disposed as the plate to be processed in the process chamber 10. Accordingly, it is possible to detect the drop of the ashing rate also in the plasma using the gas which does not contain any hydrogen atoms such as the O₂ plasma.

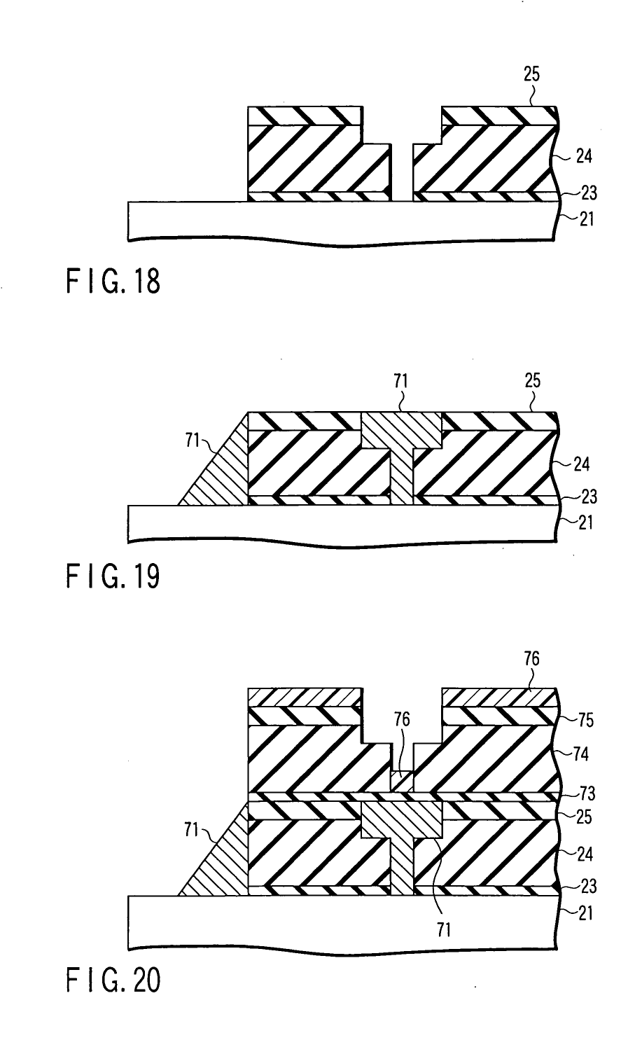

FIGS. 18 and 19 are diagrams showing a sectional structure of the wafer on which Cu is disposed on the peripheral portion. When the trench for burying the wiring is formed in the process shown in FIGS. 7 to 14 according to the first embodiment, the state shown in FIG. 18 is obtained.

Thereafter, wiring materials such as Cu are buried/formed. However, when CMP is carried out after depositing Cu, the low dielectric constant film easily peels off in the wafer peripheral portion. To prevent this, as shown in FIG. 19, a Cu film 71 is left in not only the via hole and wiring portion but also the wafer peripheral portion. Thereafter, as shown in FIG. 20, an SiC film 73, low dielectric constant film 74, and TEOS film 75 which are upper layers, and the trench for the wiring are further formed, and this process is similar to that shown in FIGS. 7 to 14.

Here, when the trench for the wiring is formed in the upper layer, a resist or carbon film 76 remains in an uppermost layer. Therefore, when the resist or carbon film 76 is ashed and accordingly removed, the Cu film 71 exists in the wafer peripheral portion, and Cu which has been sputtered by ions during ashing, sticks to the inner surface of the chamber. As a result, the increase in the number of wafer processing times brings the ashing rate fluctuations. The arrangement of the plasma processing apparatus shown in the second embodiment is so effective in such a case.

### MODIFICATION EXAMPLE

It is to be noted that the present invention is not limited to the above-described embodiments. In the first embodiment, an oxide of Cu or Ag has been used as the metal oxide structural body, but any metal oxide can be used as long as the reduction reaction takes place with the hydrogen atoms. The gas to be guided into the process chamber in the first embodiment is not limited to NH₃, any gas may also be used as long as hydrogen atoms is contained and, for example, H₂ or CH₄ can also be used.

Moreover, a configuration to excite the electric discharge is not limited. In the embodiments, parallel plate type electrodes have been used, but it is also possible to use the chamber itself as an opposed electrode disposed opposite to the electrode on which a plate to be processed is laid. Furthermore, the present invention is not necessarily limited to the ashing of the resist or the carbon film, but can also be applied to the dry etching or the forming of the film.

As described above in detail, according to the present embodiment, the metal oxide structural body which causes the reduction reaction with the hydrogen atoms is disposed in the process chamber. Accordingly, when the plasma processing is performed using the hydrogen-atom-containing gas, the hydrogen atom concentration can be decreased in the process chamber, and the low dielectric constant film can be inhibited from being modified by the hydrogen atom.

Moreover, according to the present embodiment, when the intensity of the emission by the hydrogen atom in the plasma in the process chamber is monitored, it is possible to detect the fluctuation of the ashing rate or the cleaning timing of the process chamber.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A plasma processing apparatus comprising:
a chamber in which a plate to be processed is contained;
an introductory port via which a hydrogen-atom-containing gas is guided into the chamber;
a lower electrode on which the plate to be processed is laid in the chamber;
an upper electrode which is disposed opposite to the lower electrode and which causes electric discharge in the chamber to produce a plasma;
a power supply which supplies voltage between the lower electrode and the upper electrode; and
a metal oxide structural body disposed in a part in the chamber, the metal oxide structural body being reduced when the hydrogen-atom-containing gas is introduced.

2. The plasma processing apparatus according to claim 1, wherein the metal oxide structural body includes one selected from the group consisting of Cu oxide and Ag oxide on at least the surface of the metal oxide structural body.

3. The plasma processing apparatus according to claim 1, wherein the surface of the metal oxide structural body is coated with one selected from the group consisting of Cu and Ag.

4. The plasma processing apparatus according to claim 1, wherein the metal oxide structural body is disposed in a position in the vicinity of the plasma and in the position out of ion irradiation from the plasma.

5. The plasma processing apparatus according to claim 1, wherein the metal oxide structural body is disposed in a ring shape on the inner surface of the chamber.

6. The plasma processing apparatus according to claim 1, wherein the metal oxide structural body is disposed in a cylindrical shape on the inner surface of the chamber.

7. The plasma processing apparatus according to claim 1, wherein the hydrogen-atom-containing gas, which is to be guided into the chamber, includes at least one selected from the group consisting of H₂, NH₃, and CH₄.

8. The plasma processing apparatus according to claim 1, wherein the plate to be processed is obtained by forming a pattern of a resist on a low dielectric constant film and using the resist pattern as a mask to selectively etch the low dielectric constant film, and the plasma produced between the lower electrode and the upper electrode ashes the resist.

9. The plasma processing apparatus according to claim 1, wherein the power supply is a high-frequency power supply.

10. A plasma processing apparatus comprising:
a chamber in which a plate to be processed is contained;
an introductory port via which a predetermined gas is guided into the chamber;
a lower electrode on which the plate to be processed is laid in the chamber;
an upper electrode which is disposed opposite to the lower electrode and which causes electric discharge in the chamber to produce a plasma;
a power supply which supplies voltage between the lower electrode and the upper electrode; and
a light emitting monitor which monitors intensity of emission by hydrogen atoms in the plasma in the chamber.

11. The plasma processing apparatus according to claim 10, wherein the predetermined gas to be guided into the chamber includes at least one selected from the group consisting of H₂, NH₃, CH₄, and O₂.

12. The plasma processing apparatus according to claim 10, wherein the plate to be processed includes a low dielectric constant film, and a resist pattern disposed on the low dielectric constant film to selectively etch the low dielectric constant film, and the plasma produced between the lower electrode and the upper electrode ashes the resist.

13. The plasma processing apparatus according to claim 10, wherein the power supply is a high-frequency power supply.

14. A plasma processing method comprising:
guiding a predetermined gas into a chamber in which a plate to be processed including a resist pattern on the surface is contained;
producing a plasma by electric discharge in the chamber;
ashing the resist pattern of the plate to be processed; and
monitoring a fluctuation of emission intensity of hydrogen atoms from an initial state with a photo sensor in order to detect a fluctuation of an ashing rate of the resist or a cleaning timing of the chamber.

15. The plasma processing method according to claim 14, wherein the predetermined gas to be guided into the chamber includes at least one selected from the group consisting of H₂, NH₃, CH₄, and O₂.

16. The plasma processing method according to claim 14, wherein the monitoring of the fluctuation of the emission intensity of the hydrogen atoms with the photo sensor comprises using the photo sensor having a sensitivity to a wavelength of 656 nm.

17. The plasma processing method according to claim 14, further comprising:
forming the resist pattern on a low dielectric constant film; and
using the resist pattern as a mask to selectively etch the low dielectric constant film so that the plate to be processed is obtained,
wherein the ashing of the resist pattern of the plate to be processed comprises ashing the resist pattern on the low dielectric constant film.

18. A semiconductor manufacturing apparatus comprising:
a chamber in which a semiconductor wafer as an object of resist ashing is contained;
an introductory port via which a hydrogen-atom-containing gas is guided into the chamber;
a lower electrode on which the semiconductor wafer is laid in the chamber;
an upper electrode which is disposed opposite to the lower electrode and which causes electric discharge in the chamber to produce a plasma;
a power supply which supplies voltage between the lower electrode and the upper electrode; and
a metal oxide structural body disposed in a part in the chamber, the metal oxide structural body being reduced when the hydrogen-atom-containing gas is introduced.

19. The semiconductor manufacturing apparatus according to claim 18, wherein the metal oxide structural body includes one selected from the group consisting of Cu oxide and Ag oxide on at least the surface of the body.

20. The semiconductor manufacturing apparatus according to claim 18, wherein the semiconductor wafer includes a low dielectric constant film formed above the semiconductor substrate, and a resist disposed on the low dielectric constant film in order to selectively etch the low dielectric constant film, and the plasma produced between the lower electrode and the upper electrode ashes the resist.
